(19) United States
(12) Patent Application Publication
(10) Pub. No.: US 2022/0244310 A1
(43) Pub. Date: Aug. 4, 2022

(54) ELECTRICAL OPERATING DEVICE AND METHOD FOR RECOGNIZING MALFUNCTIONS

(71) Applicant: Siemens Aktiengesellschaft, Muenchen (DE)

(72) Inventors: Dennis Persdorf, Berlin (DE); Frank Mieske, Berlin (DE)

(21) Appl. No.: 17/588,537

(22) Filed: Jan. 31, 2022

(30) Foreign Application Priority Data
Jan. 29, 2021 (EP) 21154309.5

(51) Int. Cl. G01R 31/317; H02H 1/00

(52) U.S. Cl. CPC G01R 31/31708; H02H 1/0092

(57) ABSTRACT

An electrical operating device includes measuring equipment for an electrical measured variable, and preprocessing equipment for digital measured values. The preprocessing equipment has an integrated circuit and an electronic memory component for configuring a logic circuit. A processor evaluates preprocessed measurement data and, on the basis of the evaluation, transmits data telegrams to other electrical operating devices. The preprocessing equipment calculates a respective checksum for a digital measured value, and the processor recognizes a malfunction from the measured value and the checksum of the measured value, and suppresses the evaluation and/or the transmission of the data telegrams in the event of a malfunction. There is also described a method for recognizing malfunctions.

### CROSS-REFERENCE TO RELATED APPLICATION

This application claims the priority, under 35 U.S.C. § 119, of European Patent Application EP 21154309.5, filed Jan. 29, 2021; the prior application is herewith incorporated by reference in its entirety.

### FIELD AND BACKGROUND OF THE INVENTION

The invention relates to an electrical operating device, or operating means, with measuring equipment for an electrical measured variable and preprocessing equipment for digital measured values. The preprocessing equipment comprises an integrated circuit and an electronic memory component for the configuration of a logic circuit. A processor is designed to evaluate the preprocessed measurement data and, on the basis of the evaluation, to transmit data telegrams to other electrical operating device. There is also described a method for recognizing malfunctions with the following method steps: measuring an electrical measured variable with measuring equipment and preprocessing digital measured values with preprocessing equipment. An integrated circuit and an electronic memory component for the configuration of a logic circuit are used for the preprocessing equipment and the preprocessed measurement data are evaluated by way of processor. Data telegrams based on the evaluation are transmitted to another electrical operating device.

A so-called “single event upset” (SEU) is a soft error that can be caused in semiconductor components by the passage of highly energetic, ionizing radiation (heavy ions, protons, gamma radiation, cosmic radiation, for example). It manifests, for example, as a bit-flip (a change in the state of one bit) in memory components or registers, which can lead to an incorrect function of the component concerned. The classification as a “soft error” is based on the fact that an SEU does not cause any permanent damage to the component concerned. The effect is, for example, described in Wikipedia (permalink: https://de.wikipedia.org/w/index.php?title=Single_Event_Upset&oldid=163234538).

A field programmable gate array (FPGA) is a digital integrated circuit into which a logic circuit can be loaded. Such an FPGA is, for example, known from Wikipedia (permalink: https://de.wikipedia.org/w/index.php?title=Field_Programmable_Gate_Array&oldid=206575960).

The use of FPGAs and their freely programmable logic is indispensable in modern, multifunctional protection or control devices. FPGAs based on static random access memory (SRAM) are often used; these are economical, but are subject to the SEU effect, and therefore liable to faulty functions. Such an FPGA is, for example, known from Wikipedia (permalink: https://de.wikipedia.org/w/index.php?title=Static_random-access_memory&oldid=204940730).

Analog measured values for voltages and currents are, in particular, to be considered as particularly critical, since after the digitization of the analog measured variables, a single corrupt digital measured value can lead to an incorrect decision in the device. In safety technology this could, for example, lead to an incorrect triggering of the protection device, and thus to switching off of a grid section. A high financial cost could ensue.

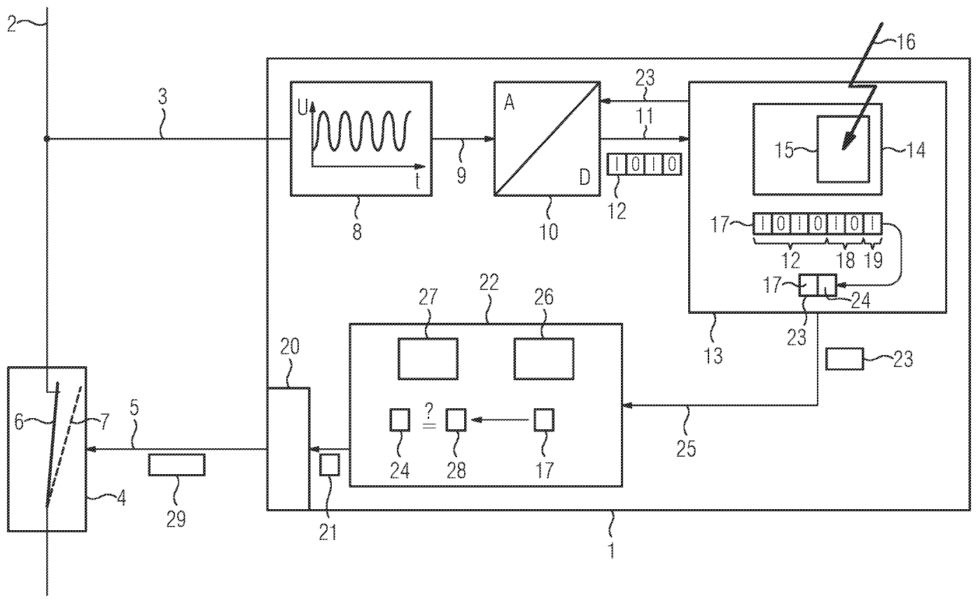

The problem of SEUs in protection devices is the topic of the publication “Single Event Upsets in SEL Relays”, Schweitzer Engineering Laboratories, Inc., 2018. A bit-flip from, for example, 0 to 1 resulting from the effect of alpha radiation is explained. The possible serious consequences of a fault in a protection device are considered, starting on page 9, under the heading “Impact on Protective Relays”. A controlled restart of the device is proposed as a reaction to errors in protection devices. The possibility of redundant systems is furthermore illustrated in FIG. 8. Three devices, including their measured value processing and processor, are, for example, operated in parallel. An evaluation is only deemed to be correct if at least two devices deliver the same result (a “2 of 3” decision). This type of construction is comparatively complex and expensive; it also entails an increased space requirement.

Carrying out a regular, automated recognition of bit errors in FPGAs is, furthermore, known. A checksum is, for example, formed here for the total configuration of a logic circuit of the FPGA; in the simplest case, this involves adding all the bits together. Checking the configuration of an FPGA by means of a cyclic redundancy check (CRC) is known from the publication “LatticeXP2 Soft Error Detection (SED) Usage Guide”, Lattice Semiconductor, 2012. It has, however, been found that in the operation of, for example, a protection device using such an FPGA, this recognition takes between a few milliseconds up to a second. A faulty function can occur within this period leading, for example, to incorrect switching operations and to the associated damage.

Flash-based FPGAs are, moreover, used in some places, which is advantageous since flash memories are largely not sensitive to SEUs for their configuration. The fact that flash-based FPGAs are significantly more expensive than SRAM-based FPGAs is disadvantageous.

### SUMMARY OF THE INVENTION

Starting out from the prior known electrical operating devices, the invention addresses the task of providing an operating device that can be manufactured comparatively economically, with which errors in the control of an energy grid that result from the effect of ionizing radiation on semiconductor components are relatively securely avoided.

With the above and other objects in view there is provided, in accordance with the invention, an electrical operating device, comprising:

measuring equipment for measuring an electrical measured variable; and

preprocessing equipment having an integrated circuit and an electronic memory component for a configuration of a logic circuit, the preprocessing equipment being configured for processing digital measured values and for calculating respective checksums for the digital measured values; and a processor configured to evaluate preprocessed measurement data received from said preprocessing equipment and, based on the evaluation, to transmit data telegrams to other electrical operating devices;

the processor being configured to recognize a malfunction based on a measured value and a respective checksum of the measured value, and to suppress the evaluation and/or the transmission of a data telegram if a malfunction is recognized.

An electrical operating device can, for example, comprise a protection device that is arranged in an electrical energy transmission or energy distribution grid and that ensures, for example, a distance protection and/or a differential protection and/or an overvoltage protection. The protection device may accordingly transmit protection commands to circuit breakers in the energy grid. An energy transmission or energy distribution grid can be assigned to the medium voltage level (above 1 kV up to 52 kV) or the high-voltage level (above 52 kV).

The measuring equipment measures, for example, current and/or voltage values as electrical measured variables. It is, for example, possible for both values to be acquired and similarly transmitted onward, for example to an analog/digital converter.

The preprocessing equipment for digital measured values is, for example, designed to retrieve digital measured values, for example from an analog/digital converter. The sampling rate can, for example, lie between 1 kHz and 100 kHz; 5 kHz to 15 kHz are preferred, while 8 kHz is even more preferred. The memory component of the configuration might be subject to bit-flips resulting from the effect of ionizing radiation which could, for example, lead to the incorrect recognition of a current or voltage value that is much too high. Accordingly, for example, a threshold value for triggering a protection command for switching off the grid would be triggered incorrectly in the processor, and this can entail considerable costs—in the millions—for the grid operator.

The processor comprises, for example, a processor unit along with electronic data storage for the temporary and/or permanent storage of data. The data telegrams can, for example, contain protection commands. In a simple case, the evaluation can, for example, involve a check as to whether predefined threshold values for current and voltage are exceeded. A data telegram can, for example, be a sequence of bits that encode different data. A protection command can, for example, be contained. The data telegrams can be transmitted, for example, by means of data communication equipment. Transmission via a power line, i.e. what is known as “powerline communication”, can be employed here. Transmission by data cable (e.g. Ethernet via copper wires, or optical fibers) or by radio (long-range radio, 2G, 3G, 4G, 5G) can alternatively also take place. Transmission over the Internet with the aid of TCP/IP can, for example, also take place.

The “other operating devices” or operating means may, by way of example, be switches in the energy grid.

The checksum is, for example, formed directly from the bits of the digital measured value, and is reproducible, meaning that it also later permits a definite statement as to whether the checksum has been calculated from the bit sequence that is then present. If that is the case, it can be assumed that the digital measured value has been correctly transmitted and processed. If it is not the case, it can be assumed that an error such as, for example, a bit-flip has occurred.

The preprocessing equipment can for example forward the associated checksum, together with the underlying digital measured value, i.e., a bit sequence, to the processor. A checksum can again be calculated there on the basis of the bit sequence of the digital measured value and compared with the transmitted checksum. Comparison equipment can, for example, be provided for this purpose, formed in hardware or software. The comparison equipment is preferably assigned to the processor.

If the two checksums do not agree, a malfunction must be assumed, which means that there has been a change in the underlying digital measured value. This must therefore not be trusted, and must be ignored for further evaluation steps. A data telegram with, for example, a protection command is not transmitted, because the transmission is blocked or because no previous evaluation of the faulty digital measured value has taken place at all. Over-functioning of the device is thus avoided.

The approach described, however, does not provide for 100% security in the recognizing of bit-flips because, for example, a bit-flip that occurs after generating the digital measured values and before the calculation of the checksums is not recognized. The probability for the occurrence of this error is, however, vanishingly small, since the probability of occurrence of an error in the presence of radiation is proportional to the cross-sectional area. Since the entire semiconductor structure is significantly larger than the area of the preprocessing equipment required for calculating the checksum, only a few percent of all the bit-flips occur before the calculation of the checksum.

A significant advantage of the present solution is that no hardware that may already have been installed needs to be changed. Integration can, rather, take place through an update of the FPGA firmware and software in devices that are already present or have already been installed, or in future devices. An enormous potential cost saving thereby results, on the one hand for manufacturers of electrical operating means, who can make their devices more secure and more reliable through a simple update, and on the other hand for energy grid operators who can further reduce incorrect actions and consequent costs without having to install new hardware beforehand. Earlier possible solutions with redundant signal processing chains, which are relatively secure but expensive, are also omitted.

In a preferred embodiment of the electrical operating means according to the invention, a checksum of the bits of the digital measured value is formed for the checksum. In a simple case, the checksum 2 is calculated, for example, for the bit sequence 10010 by adding the individual bits of the bit sequence. A cyclic redundancy check can alternatively, for example, be performed, in which a polynomial division is used for the determination of the checksums.

In a further preferred embodiment of the electrical operating means according to the invention, a weighting of the bits of the digital measured value is also performed and/or channel information is taken into consideration for the checksum. Weighting the bits makes it possible to recognize bit exchanges. If, for example, the first bit of the bit sequence 10010 is weighted most strongly (with the factor 5), and the last bit is the weakest (with the factor 1), the checksum is found as 5+0+0+2+0=7. If a bit-flip of the type 10100 is present, then a checksum of 5+0+3+0+0=8 results instead. The error can be recognized reliably. Electrical operating means that comprise multiple phases and/or multiple measurement inputs often operate with a series of channels. A bit sequence that encodes for the channel is accordingly also assigned to the digital measured value. If a bit-flip occurs here, this also leads to a malfunction because, for example, a voltage measured value of first measuring equipment is taken in the processor to be a current measured value of second measuring equipment. It is therefore expedient to check the correct channel assignment also with the checksum. The algorithm used for this checksum formation is designed such that it can be implemented in real time with few resources.

In a further preferred embodiment of the electrical operating means according to the invention, the processor is designed to prevent the evaluation and/or transmission of data telegrams in the event of a malfunction at least until a malfunction is no longer recognized on the basis of a further measured value and of the respective checksum of the further measured value. If, for example, an analog measurement signal of the measuring equipment is sampled at 8 kHz, then 8000 digital measured values, together with the assigned checksum, are prepared and transmitted each second. In this example, a new digital measured value, together with the assigned checksum, would be available after 1/8000 seconds. Triggering a data telegram would be suppressed until the new digital measured value had also been checked and recognized as correct. If this new measured value shows, for example, that a limit value has not been violated, then no data telegram is transmitted. If the new measured value confirms that the limit value has been violated, then a data telegram is transmitted.

In a further preferred embodiment of the electrical operating means according to the invention, the processor is designed to enable the evaluation and/or the transmission of data telegrams in the event that there is no malfunction.

In a further preferred embodiment of the electrical operating means according to the invention, the integrated circuit comprises a field programmable gate array, and the electronic memory component comprises a static random access memory (SRAM). This is an advantage, since static random access memory (SRAM) semiconductor components are particularly sensitive to bit-flips as a result of ionizing radiation.

In a further preferred embodiment of the electrical operating means according to the invention, an analog/digital converter is designed to convert an analog electrical measured variable into a digital measured value at a predefined sampling rate. This is an advantage, because analog measured values can in this way easily be converted into digital measured values at a predefined sampling rate.

In a further preferred embodiment of the electrical operating means according to the invention, the operating means comprises a protection device, and the data telegrams comprise protection commands, while the protection device comprises data communication equipment for transmitting the data telegrams to switches as other operating means in an energy grid.

With the above and other objects in view there is also provided, in accordance with the invention, a method for recognizing malfunctions in an electrical operating device with which errors in the control of an energy grid resulting from the effect of ionizing radiation on semiconductor components are avoided.

That is, there is provided a method for recognizing malfunctions in an electrical operating device, the method comprising:

measuring an electrical measured variable by measuring equipment; and

preprocessing digital measured values by preprocessing equipment having an integrated circuit and an electronic memory component for a configuration of a logic circuit, to generate preprocessed measurement data;

calculating respective checksums for the digital measured values by the preprocessing equipment, and

receiving and evaluating the preprocessed measurement data by a processor, and recognizing a malfunction on a basis of a measured value and a respective checksum of the measured value by the processor;

transmitting data telegrams based on the evaluating step to another electrical operating device, but suppressing an evaluation and/or a transmission of the data telegrams in the event of a malfunction.

The above details and advantages that are described in the context of the device according to the invention correspondingly apply to the method according to the invention and its embodiments as explained above for the electrical operating means according to the invention.

Other features which are considered as characteristic for the invention are set forth in the appended claims.

Although the invention is illustrated and described herein as embodied in an electrical operating device and a method for recognizing malfunctions, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of a specific embodiment when read in connection with the accompanying drawing.

### BRIEF DESCRIPTION OF THE FIGURE

The sole FIGURE of the drawing is a schematic illustration of an exemplary embodiment of an electrical operating device according to the invention.

### DETAILED DESCRIPTION OF THE INVENTION

An electrical line 2 of an energy transmission grid of the high-voltage level is connected (possibly via a non-illustrated measuring transducer) by means of the line 3 to an electrical operating means 1 that is designed as a protection device. A measured value processing chain is illustrated in the protection device 1.

Measuring equipment 8 for an electrical measured variable is designed to determine the time profile of a voltage U. Analog measured values are output via an analog connection 9, which in this case is an instantaneous voltage value. The instantaneous voltage value is converted in an analog/digital converter 10 at a predefined sampling rate of, for example, 8 kHz into a bit sequence (e.g. “1010”), which indicates a digital measured value 12.

This digital measured value 12 is, for example, retrieved by preprocessing equipment 13 for digital measured values 12. The preprocessing equipment here comprises an integrated circuit 14 and an electronic memory component 15 for the configuration of a logic circuit, wherein the integrated circuit comprises a field programmable gate array (FPGA) and the electronic memory component comprises a static random access memory (SRAM).

As soon as it arrives, the FPGA adds a checksum 24, for example a checksum of the bits of the digital measured value 12, to each digital measured value 12. Channel information 19 can furthermore also be taken into consideration for the checksum 24. A timestamp 18 can also be taken into consideration. A bit sequence 17 thus results, for which the checksum 24 is calculated, potentially also with a weighting of the bits of the digital measured value. If high-energy radiation, for example ionizing radiation such as gamma radiation 16, now acts on the electronic memory component 15, what is known as an SEU can occur. This can lead to a bit-flip within the bit sequence 17, which would consequently lead to a changed checksum 24. This means that the result of an SEU is that the checksum 24 in the bit sequence 24 no longer matches the now changed bit sequence 17 with the digital measured value.

The checksum 24 is now carried as the bit sequence 23, together with the bit sequence 17 that contains at least the digital measured value 12, through the further measured value chain.

The bit sequence 23 is made available via the data line 25 to a processor installation or processor 22. The processor 22 has a central processing unit (CPU) 26 and a data memory 27.

The processor 22 is configured to evaluate the preprocessed measurement data, i.e., the bit sequence 17 from the bit sequence 23. From the measured value 12 and the further information 18, 19 in the bit sequence 17, as well as the respective checksum 24, it can recognize a malfunction and, in the event of a malfunction, suppress the evaluation and/or the transmission of data telegrams to other electrical operating means 4. This recognizing of a malfunction takes place in that a second checksum 28 is calculated from the bit sequence 17, and compared with the checksum 24. If the two checksums match, the bit sequence 17 is present in unchanged form—no SEU has occurred. If the two checksums do not match, an error such as a bit-flip of one or a number of bits must be suspected.

If no malfunction is present, the processor 22 can evaluate the digital measured value 12 etc., and, if predefined limit values are violated, can for example execute a protection function for the electrical energy grid. In this case, the processor 22 sends a protection command 21 to data communication equipment 20 that is designed to transmit the protection command 21 as a data telegram 29 over a data communication connection 5 to a switch 4.

When, for example, the data telegram 29 is received in a controller for the switch 4, the switch 4 is triggered. In that case, the switch 4 changes from a closed state 6 into an open state 7.

1. An electrical operating device, comprising:
measuring equipment for measuring an electrical measured variable; and
preprocessing equipment having an integrated circuit and an electronic memory component for a configuration of a logic circuit;
said preprocessing equipment being configured for processing digital measured values and for calculating respective checksums for the digital measured values; and
a processor configured to evaluate preprocessed measurement data received from said preprocessing equipment and, based on the evaluation, to transmit data telegrams to other electrical operating devices;
said processor being configured to recognize a malfunction based on a measured value and a respective checksum of the measured value, and to suppress an evaluation and/or a transmission of a data telegram if a malfunction is recognized.

2. The electrical operating device according to claim 1, wherein a checksum of bits of a digital measured value is formed for the checksum.

3. The electrical operating device according to claim 2, wherein the bits of the digital measured value is also weighted and/or channel information is taken into consideration for the checksum.

4. The electrical operating device according to claim 1, wherein said processor is configured to prevent an evaluation and/or transmission of data telegrams if a malfunction is recognized, at least until a malfunction is no longer recognized on a basis of a further measured value and of a respective checksum of the further measured value.

5. The electrical operating device according to claim 1, wherein said processor is configured to enable an evaluation and/or a transmission of data telegrams if no malfunction is recognized.

6. The electrical operating device according to claim 1, wherein said integrated circuit comprises a field programmable gate array and said electronic memory component comprises a static random access memory.

7. The electrical operating device according to claim 1, which comprises an analog/digital converter configured to convert the electrical measured variable, being an analog electrical measured variable, into a digital measured value at a predefined sampling rate.

8. The electrical operating device according to claim 1, further comprising a protection device, and wherein the data telegrams comprise protection commands and the protection device comprises data communication equipment for transmitting the data telegrams to switches being the other operating devices in an energy grid.

9. A method for recognizing malfunctions in an electrical operating device, the method comprising:
measuring an electrical measured variable by measuring equipment; and
preprocessing digital measured values by preprocessing equipment having an integrated circuit and an electronic memory component for a configuration of a logic circuit, to generate preprocessed measurement data;
calculating respective checksums for the digital measured values by the preprocessing equipment, and
receiving and evaluating the preprocessed measurement data by a processor, and recognizing a malfunction on a basis of a measured value and a respective checksum of the measured value by the processor;
transmitting data telegrams based on the evaluating step to another electrical operating device, but suppressing an evaluation and/or a transmission of the data telegrams in the event of a malfunction.

10. The method according to claim 9, which comprises forming the checksum from bits of the digital measured value.

11. The method according to claim 10, which further comprises weighting the bits of the digital measured value and/or taking channel information into consideration for the checksum.

12. The method according to claim 9, which comprises, on recognizing a malfunction, preventing the evaluation and/or the transmission of data telegrams
